(19) United States
(12) Patent Application Publication
(10) Pub. No.: US 2009/0078929 A1
(43) Pub. Date: Mar. 26, 2009

(54) NANOWIRE DEVICE AND METHOD OF MAKING A NANOWIRE DEVICE

(75) Inventor: Stephanie A. Getty, Washington, DC (US)

Correspondence Address: NASA GODDARD SPACE FLIGHT CENTER, 8800 GREENBELT ROAD, MAIL CODE 140.1, GREENBELT, MD, 20771, US

(73) Assignee: NASA Headquarters, Washington, DC (US)

(21) Appl. No.: 11/861,457

(22) Filed: Sep. 26, 2007

(51) Int. Cl. H01L 29/06; H01L 21/311

(52) U.S. Cl. 257/14; 438/694; 257/E21.305

(57) ABSTRACT

A method of making nanowires includes providing a silicon substrate having a silicon dioxide insulation on the surface thereof. The silicon dioxide is etched to form one or more pillars, each having a plurality of sidewalls. A thin film of gold is deposited on a sidewall and is subjected to an annealing process. The annealing process causes the gold film to form a globular catalyst particle. The structure is placed in an LPCVD furnace into which is introduced silane gas. Silicon from the gas migrates through the catalyst particle and grows a nanowire from the sidewall of the pillar to a desired length. Electrical contacts are provided at each end of the nanowire to create an active component useable in an electronic circuit.

### ORIGIN OF INVENTION

The invention described herein was made by an employee of the United States Government and may be manufactured and used by or for the Government for Governmental purposes without the payment of any royalties thereon or therefor.

### BACKGROUND OF THE INVENTION

A nanowire is an extremely thin wire having a diameter of around a few tens of nanometers (1 nm=10⁻⁹ meters) or less and is generally fabricated from a semiconductor material. Devices made with nanowires may be used in miniature electronic components for use in integrated electronics, detectors and sensors. For example, nanowire devices may be used for the analysis and identification of biological, chemical and environmental conditions. Fields expected to benefit from this technology include water purification, sanitation, agriculture, alternative energy, computers, communication and medicine, to name a few.

Prior methods for the fabrication of nanowires include the scattered random growth on a substrate, which prevented the orderly assembly of an array of such nanowires. In another method, trenches are formed in a silicon layer and a catalyst is deposited on the walls of the trenches. When the trench structure is placed in an appropriate atmosphere, silicon nanowires start growing toward an opposite wall of the trench. A problem with this approach is that the catalyst is not uniformly deposited on the trench wall surface resulting in the growth of several nanowires from various catalyst particles of different sizes.

### SUMMARY OF THE INVENTION

The disclosure presents a method of making nanowire devices that are fabricated in orderly arrays and have well-defined nanowire growth.

One aspect is a method of making a nanowire comprising providing a semiconductor substrate having a layer arrangement on a first surface thereof; etching the layer arrangement to form at least one pillar having a plurality of sidewalls; depositing a thin film of a catalyst on at least one of the sidewalls; annealing the thin film to form, from the thin film, a globular catalyst particle on the sidewall; and flowing a gas over the catalyst particle, the gas containing a material to form the nanowire.

The step of flowing may include continuously flowing the gas over the catalyst particle to grow the nanowire from the surface of the sidewall on which the catalyst particle is located until the nanowire attains a predetermined length.

The step of etching may include etching the layer arrangement to form a square pillar having four sidewalls. The method may further comprise growing nanowires on opposite sidewalls of the pillar. A plurality of nanowires may be formed on a plurality of pillars wherein the nominal diameters of the plurality of nanowires are equal.

In one embodiment, the step of providing a semiconductor substrate having a layer arrangement on a first surface thereof may include providing a semiconductor substrate comprising silicon with a layer arrangement comprising a single layer of silicon dioxide.

In another embodiment, the step of providing a semiconductor substrate having a layer arrangement on a first surface thereof may include providing a layer arrangement comprising a first layer of an insulator and a second layer of a semiconductor.

Another aspect is an apparatus comprising a semiconductor substrate; at least one pillar disposed on the semiconductor substrate, the at least one pillar having a plurality of sidewalls; and a nanowire extending from one of the sidewalls. In one embodiment, the pillar is a square pillar having four sidewalls. The apparatus may further comprise a second nanowire extending from an opposite one of the sidewalls.

In one embodiment, the apparatus comprises a plurality of pillars and a respective plurality of nanowires. The nominal diameters of the plurality of nanowires may be equal.

The disclosure will be better understood, and further features and advantages thereof will become more apparent from the following description, taken in conjunction with the accompanying drawings.

### BRIEF DESCRIPTION OF THE DRAWINGS

In the drawings, which are not necessarily to scale, like or corresponding parts are denoted by like or corresponding reference numerals.

FIGS. 1A to 1F are side views of fabrication steps in accordance with the present invention.

FIGS. 2A to 2F are isometric views of the process steps of FIGS. 1A-1F.

FIG. 3 is a plan view of an array of nanowire devices.

FIGS. 4A and 4B illustrate an alternate method of pillar fabrication.

FIGS. 5A and 5B illustrate another alternate method of pillar fabrication.

### DETAILED DESCRIPTION OF THE PREFERRED EMBODIMENTS

Nanowires made of silicon are most compatible with conventional integrated circuits. Accordingly the present invention will be described, by way of example, with respect to devices made of silicon, although it is to be understood that other semiconductor materials are equally applicable.

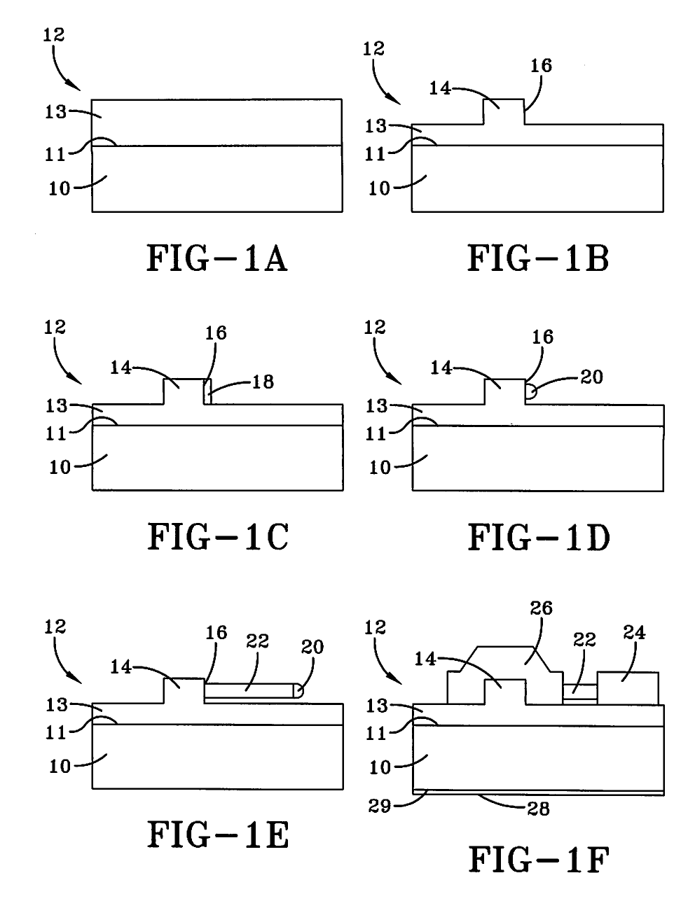

The process starts with a structure as illustrated in FIG. 1A, which includes a doped silicon substrate 10 covered on a first surface 11 by a layer arrangement 12. In this embodiment, the layer arrangement 12 is comprised of a single insulating layer 13 such as SiO₂ (silicon dioxide). The insulating layer 13 is patterned and etched to form at least one, but preferably a plurality of pillars, of which one, 14 is illustrated in FIG. 1B. The pillar 14 includes a plurality of sidewalls. In the embodiment illustrated, a square pillar is formed having a sidewall 16.

As illustrated in FIG. 1C, a catalyst 18 (such as gold) is deposited onto the sidewall 16 to a predetermined thickness. Since the wall dimension is known, as well as the thickness of the gold applied, the exact amount of gold on the sidewall 16 is known. The structure of FIG. 1C is subjected to an annealing process at a temperature of around 450° C. in an inert atmosphere such as nitrogen, which causes the gold catalyst 18 to form a hemispherical globule or particle 20 on the sidewall 16, as illustrated in FIG. 1D. The volume of the catalyst particle 20 is given by:

V=1/12πD³,

where V is the volume and D is the diameter of the catalyst particle. The value V is also the volume of gold on the sidewall 16:

V=t*h*w,

where t is the thickness of the applied gold, h is the height of the sidewall and w is the width of the sidewall.

Thus, by controlling the amount of gold applied, the diameter of the catalyst particle may be determined. The silicon nanowire to be grown has an associated electronic band gap, which is tunable by controlling the diameter of the nanowire. The diameter of the nanowire in turn, is controllable by the diameter of the catalyst particle. Therefore, by controlled application of the gold catalyst, the band gap of the nanowire may be selected. Thus, the potential exists for fabricating an array of uniform nanowires with energy scales tailored to a specific application.

The structure of FIG. 1D is placed in an LPCVD (low pressure chemical vapor deposition) furnace at a temperature of around 450° C. in flowing silane gas to grow a silicon nanowire 22, as illustrated in FIG. 1E. The silane gas (SiH4) contains the material (silicon) that will form the nanowire. Basically, the gold catalyst breaks down the silane into its component parts of silicon and hydrogen. The silicon material migrates through the gold catalyst particle and attaches to the sidewall 16 of pillar 14 where the growth process continues until a desired length of silicon nanowire 22 is obtained.

Thereafter, and as illustrated in FIG. 1F, contacts, such as gold contacts, are deposited on the structure. More particularly, first contact 24 covers the distal end of nanowire 22 and second contact 26 contacts the end of nanowire 22 attached to sidewall 16. Although not necessary, contact 26 is shown as also covering the pillar 14. A contact 28 is also applied to the underside 29 of substrate 10.

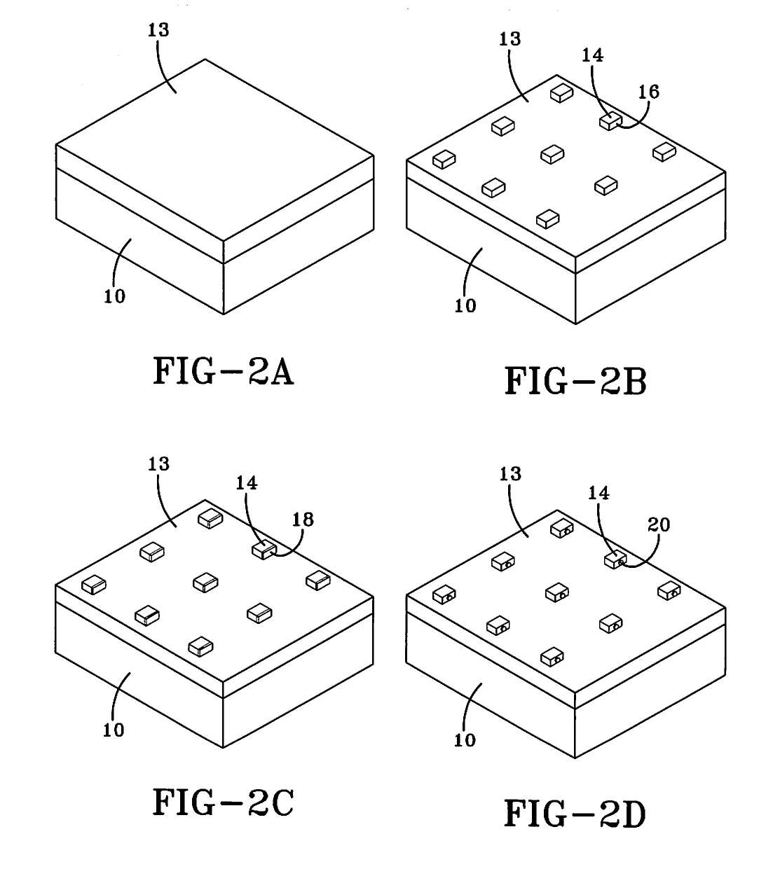

FIGS. 2A to 2F show the process steps of FIGS. 1A to 1F in isometric views as applied to an ordered array of nanowire devices.

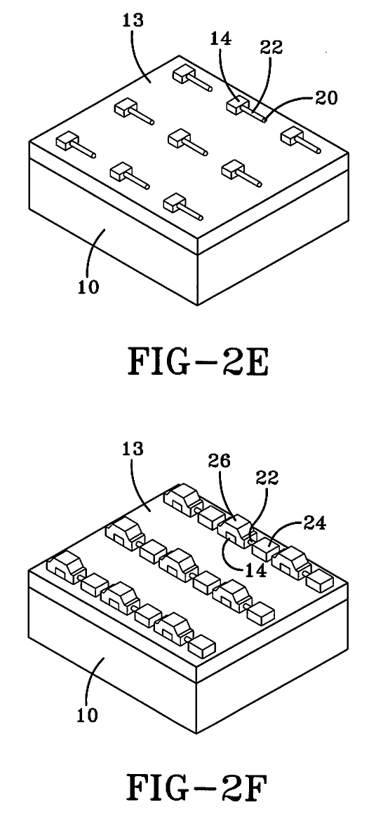

FIG. 3 illustrates the array of FIG. 2F in plan view, as applied to a multi-array device on a wafer 30, and with an additional nanowire 22 extending from the opposite sidewall of each of the pillars 14 of FIG. 2E, for example. The wafer 30 includes a plurality of contact pads 32 surrounding the array on the periphery of the wafer 30. The ordered array of nanowire devices shown in FIG. 3 is built around an N×M array of pillars, where, by way of example, N=M=3. In this arrangement an additional nanowire 22 is grown on a sidewall opposite to the nanowire growth in FIG. 1E, and one end of the additional nanowire 22 is covered by contact 24′. Each nanowire device of FIG. 3 includes contacts 24, 24′ and 26 connected to respective contact pads 32, with each nanowire contact being electrically connected to a separate one of the contact pads 32. A contact pad 32′ is not connected to any nanowire contact but rather makes electrical connection with contact 28 (FIG. 1F) on the undersurface 29 of substrate 10.

In one embodiment, each half of the nanowire device can form a FET (field effect transistor) with contact 24′ connected to the source of the FET, contact 26 connected to the drain, and contact 28 (FIG. 1F) connected to the gate of the FET. The other half of the nanowire device can also form an additional FET with contact 26 constituting the source and contact 24 constituting the drain, or vice versa. With this arrangement, nanowires 22 constitute the channels of the FETs. Although the gate is common to all the transistors, separate gates may also be formed.

In FIG. 3, the array of nanowire devices is illustrated as being uniformly positioned on the wafer. In other embodiments, the nanowire devices may be intentionally and controllably placed at predetermined locations on the wafer for enhanced flexibility and compatibility with other circuit or sensor components. That is, the nanowire devices can be confined to predetermined locations and large areas can be otherwise available for other integrated circuit components. In the embodiment of FIG. 3, two nanowires extend from opposite sidewalls of a pillar. By rotating the structure during gold catalyst deposition, nanowires may be grown from all four of the pillar sidewalls.

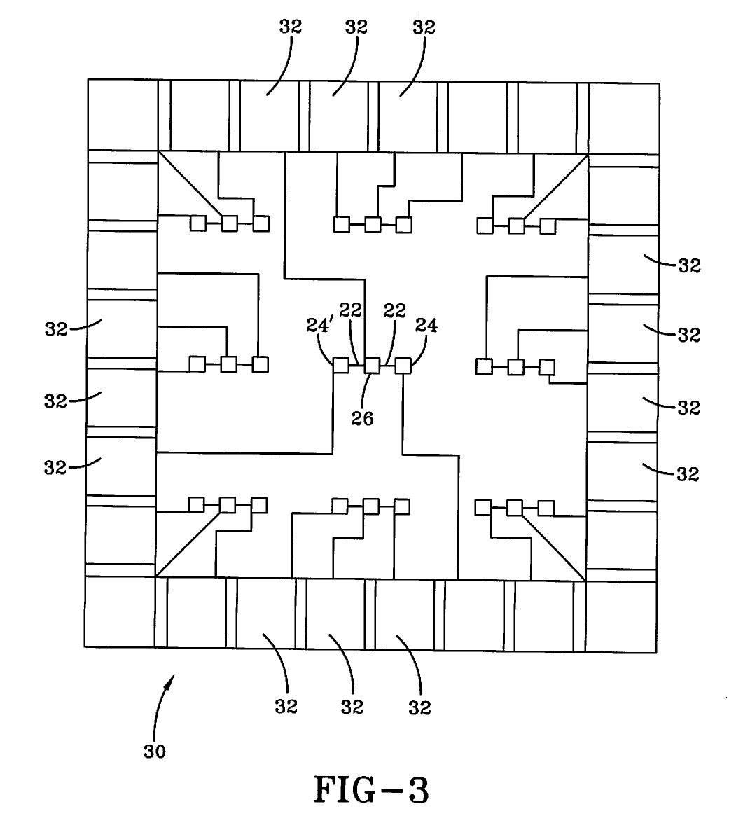

FIGS. 4A and 4B illustrate an alternate method of forming pillars. FIG. 4A illustrates a doped substrate 34 having a layer arrangement 36 on a top surface 38 thereof. The layer arrangement 36 includes a first insulating layer 40 and a second layer 42 of a relatively thick non-electrically conducting semiconductor 42. As illustrated in FIG. 4B, the semiconductor layer 42 is partially etched to form a plurality of pillars 43 upon which the nanowires will be grown. Electrical isolation between nanowires will be maintained since the semiconductor layer 42 is non-conductive.

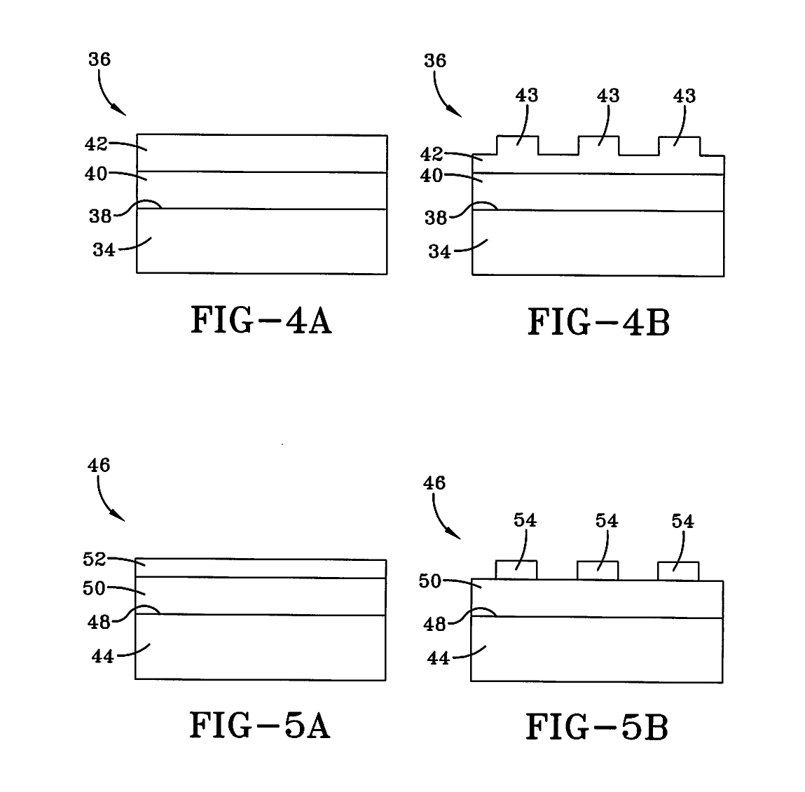

FIGS. 5A and 5B show another method of pillar formation. In FIG. 5A, a doped substrate 44 has a layer arrangement 46 on the top surface 48 thereof. The layer arrangement 46 is comprised of a first layer 50 of insulating material and a second layer of a relatively thin electrically conducting or non-conducting semiconductor 52. As illustrated in FIG. 5B, the semiconductor layer 52 is etched down to the insulating layer 50 to form a plurality of pillars 54 upon which the nanowires will be grown.

There has been described a method of growing nanowires from a known volume of catalyst seeding material so that diameters of the nanowires are nominally identical. Because semi-conducting band gap depends only on the diameter of the nanowire, the electronic structure is uniform within the array of nanowires. Further, the diameter becomes a tunable parameter in the fabrication so that an end user may tailor the nanowire energy scale to suit a particular application.

Numerous changes, alterations and modifications to the described embodiments are possible without departing from the spirit and scope of the invention as defined in the appended claims, and equivalents thereof.

What is claimed is:

1. A method of making a nanowire, comprising:
providing a semiconductor substrate having a layer arrangement on a first surface thereof;
etching the layer arrangement to form at least one pillar having a plurality of sidewalls;
depositing a thin film of a catalyst on at least one of the sidewalls;
annealing the thin film to form, from the thin film, a globular catalyst particle on the sidewall; and
flowing a gas over the catalyst particle, the gas containing a material to form the nanowire.

2. The method of claim 1 wherein the step of flowing includes continuously flowing the gas over the catalyst particle to grow the nanowire from the surface of the sidewall on which the catalyst particle is located until the nanowire attains a predetermined length.

3. The method of claim 1 wherein the step of etching includes etching the layer arrangement to form a square pillar having four sidewalls.

4. The method of claim 3 further comprising growing nanowires on opposite sidewalls of the pillar.

5. The method of claim 1 wherein the etching step includes etching the layer arrangement to form an N×M array of the pillars.

6. The method of claim 5 wherein the etching step includes etching the layer arrangement to form an N×M array of the pillars, where N=M.

7. The method of claim 1 further comprising applying a first electrical contact to a distal end of the nanowire and applying a second electrical contact to an end of the nanowire attached to the pillar.

8. The method of claim 7 further comprising applying an electrical contact to an undersurface of the substrate.

9. The method of claim 7 further comprising covering the pillar with the second electrical contact.

10. The method of claim 7 wherein a plurality of nanowires are formed on a plurality of pillars and further wherein nominal diameters of the plurality of nanowires are equal.

11. The method of claim 1 wherein depositing a thin film of a catalyst on at least one of the sidewalls includes depositing a thin film catalyst comprising gold.

12. The method of claim 1 wherein flowing a gas over the catalyst particle includes flowing silane gas over the catalyst particle.

13. The method of claim 1 wherein providing a semiconductor substrate having a layer arrangement on a first surface thereof includes providing a semiconductor substrate comprising silicon with a layer arrangement comprising a single layer of silicon dioxide.

14. The method of claim 1 wherein providing a semiconductor substrate having a layer arrangement on a first surface thereof includes providing a layer arrangement comprising a first layer of an insulator and a second layer of a semiconductor.

15. The method of claim 14 wherein the second layer semiconductor is electrically non-conducting and wherein etching the layer arrangement includes partially etching the second layer semiconductor to form the pillars.

16. The method of claim 14 wherein the second layer is one of electrically conducting or non-conducting and wherein etching the layer arrangement includes etching the second layer semiconductor down to the first layer insulator to form the pillars.

17. An apparatus, comprising:
a semiconductor substrate;
at least one pillar disposed on the semiconductor substrate, the at least one pillar having a plurality of sidewalls; and
a nanowire extending from one of the sidewalls.

18. The apparatus of claim 17 wherein the pillar is a square pillar having four sidewalls.

19. The apparatus of claim 17 further comprising a second nanowire extending from an opposite one of the sidewalls.

20. The apparatus of claim 17 further comprising a plurality of pillars and a respective plurality of nanowires.

21. The apparatus of claim 20 wherein nominal diameters of the plurality of nanowires are equal.

22. The apparatus of claim 17 further comprising a first electrical contact applied to a distal end of the nanowire and a second electrical contact applied to an end of the nanowire attached to the pillar.

23. The apparatus of claim 17 further comprising an electrical contact applied to an undersurface of the substrate.

24. The apparatus of claim 22 wherein the second electrical contact covers the pillar.

25. The apparatus of claim 17 further comprising a plurality of contact pads around the periphery of the substrate wherein the first and second electrical contacts are connected with respective contact pads.
